(19) United States
(12) Patent Application Publication
(10) Pub. No.: US 2015/0122971 A1
(43) Pub. Date: May 7, 2015

(54) 3D STACKED IMAGE SENSOR

(71) Applicant: Silicon Optronics, Inc., Hsinchu (TW)

(72) Inventor: Xinping He, Saratoga, CA (US)

(73) Assignee: SILICON OPTRONICS, INC., Hsinchu (TW)

(21) Appl. No.: 14/070,365

(22) Filed: Nov. 1, 2013

(51) Int. Cl. H01L 27/148; H01L 27/146

(52) U.S. Cl. CPC H01L 27/14831; H01L 27/14634; H01L 27/14643; H01L 27/14636
USPC 250/208.1

(57) ABSTRACT

An active pixel sensor comprises a sensor die and a circuit die. The sensor die comprises a plurality of pixels. Each pixel includes a light sensitive element and a transfer gate, a floating diffusion region, and a reset gate. The circuit die comprises a plurality of processing and amplification circuits associated with the reset gates of the sensor die. The sensor die is interconnected with the circuit die utilizing a plurality of inter-die interconnects each coupled to a source node of the reset gate on the sensor die and a node of a processing and amplification circuit on the circuit die.

### TECHNICAL FIELD

The present disclosure relates to Complementary Metal-Oxide-Semiconductor Transistor (CMOS) image sensors, and more particularly, to a 3D stacked active pixel sensor.

### BACKGROUND

An active pixel sensor (APS) combines a photodiode with processing and amplification circuitry in each pixel to form an image sensor. In some implementations, the associated circuitry is implemented with four transistors, and may be referred to as a 4T APS. Such sensors are commonly found in devices such as cell phone cameras, digital cameras, and web cameras.

Smaller APS and smaller pixels are enabled by the improvements in semiconductor processing. A consequence of smaller pixel size is that the pixel's photodiode must also shrink to accommodate the smaller APS area. Less light is then able to fall on each pixel, and as a result image quality is reduced. Conventionally, stacked or vertically integrated image sensors are used, wherein a sensor die includes the photodiode portion stacked atop a circuitry die, which contains the remaining circuitry of an APS imager. In a stacked sensor configuration, the photodiode may occupy greater surface area. Manufacturing of the two dies independently allows for optimization for photodetection and electronics purposes.

The 4T APS imager may include a floating diffusion. These floating diffusion areas can cause defects or high dark current. In addition, non-standard CMOS process steps may be needed to form a diffusion area.

### SUMMARY OF THE INVENTION

According to an embodiment of the invention, an active pixel sensor comprises a sensor die and a circuit die. The sensor die comprises a plurality of pixels, wherein each pixel includes a light sensitive element and a transfer gate, a floating diffusion region, and a reset gate. The circuit die comprises a plurality of processing and amplification circuits associated with the reset gates of the sensor die. The sensor die is interconnected with the circuit die utilizing a plurality of inter-die interconnects each coupled to a source node of the reset gate on the sensor die and a node of a processing and amplification circuit on the circuit die.

According to another embodiment of the invention, an active pixel sensor comprises a sensor die and a circuit die. The sensor die comprises a plurality of pixels, wherein each pixel includes a light sensitive element and a transfer gate, a plurality of floating diffusion regions associated with the plurality of transfer gate. The circuit die comprises a plurality of reset gates and a plurality of processing and amplification circuits. The sensor die is interconnected with the circuit die utilizing a plurality of inter-die interconnects each coupled to a drain node of a transfer gate on the sensor die and a node of a floating diffusion region on the circuit die.

### BRIEF DESCRIPTION OF THE DRAWINGS

The present invention is illustrated in an exemplary manner by the accompanying drawings. The drawings should be understood as exemplary rather than limiting, as the scope of the invention is defined by the claims.

FIG. 1 is a plan view of a sensor die included in an image sensor having two stacked semiconductor dies according to an embodiment of the invention.

FIG. 2 is a cross-sectional view of two stacked semiconductor dies forming an image sensor of FIG. 1.

FIG. 3 is a schematic diagram showing a structure of stacked image sensor with a floating diffusion region in a sensor die according an embodiment of the invention.

FIG. 4 is a schematic of a stacked image sensor in accordance with another embodiment of the invention.

FIG. 5 is a schematic of a stacked image sensor in accordance with another embodiment of the invention.

FIG. 6A is a schematic of a stacked image sensor in accordance with another embodiment of the invention.

FIG. 6B is a schematic of a stacked image sensor in accordance with another embodiment of the invention.

FIG. 7 is a schematic of a stacked image sensor in accordance with another embodiment of the invention.

FIG. 8 is a schematic diagram of a shared processing and amplification architecture that can be implemented in an image sensor having two semiconductor dies in an embodiment in accordance with the invention.

FIG. 9 is a schematic diagram illustrating the structure in which a given floating diffusion region in a sensor die is shared by four photodiodes of that sensor die according to an embodiment of the invention.

FIG. 10 is a diagram showing a timing for the operation of the sensor 30.

### DETAILED DESCRIPTION

As will be discussed below, the disclosed embodiments allow for larger light sensitive elements in spite of shrinking image sensor circuit features through the use of a stacked configuration of sensor and circuit dies. Further, some of the disclosed embodiments achieve a stacked image sensor without requiring a floating diffusion region on the circuit die.

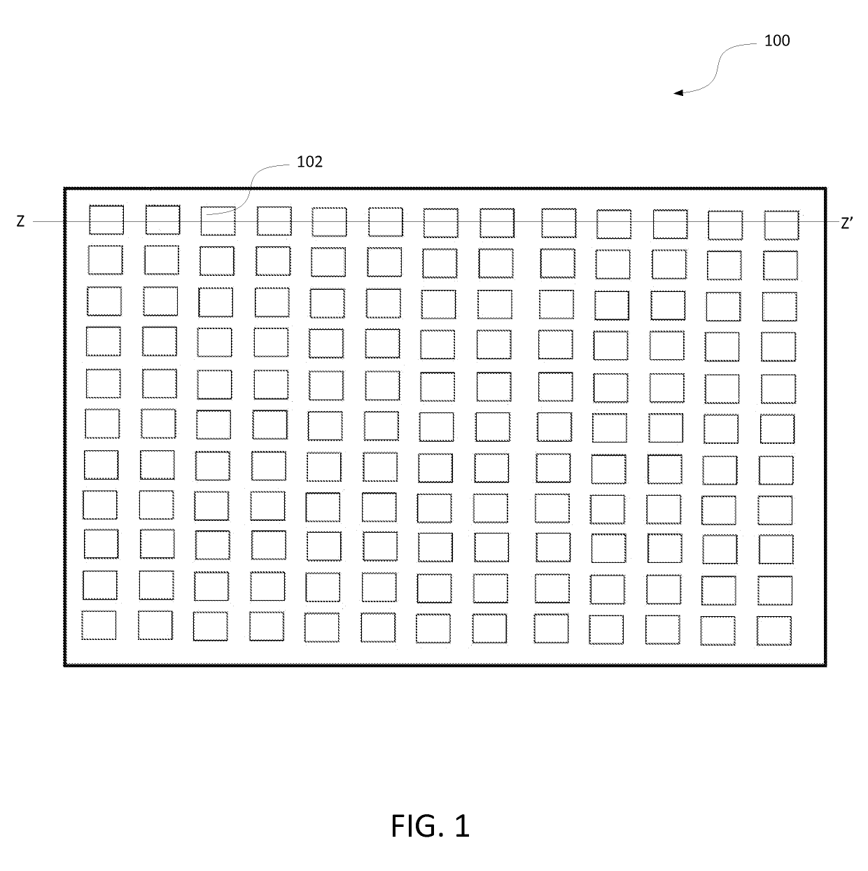

FIG. 1 is a plan view of a sensor die portion of an image sensor having two stacked semiconductor dies according to an embodiment of the invention. Image sensor 100 is implemented as an active pixel sensor (APS), such as, for example, a CMOS image sensor. Image sensor 100 includes pixels 102 arranged in an array of rows and columns. Image sensor 100 can have any number of pixels regions, such as, for example, 1280 columns by 960 rows of pixels.

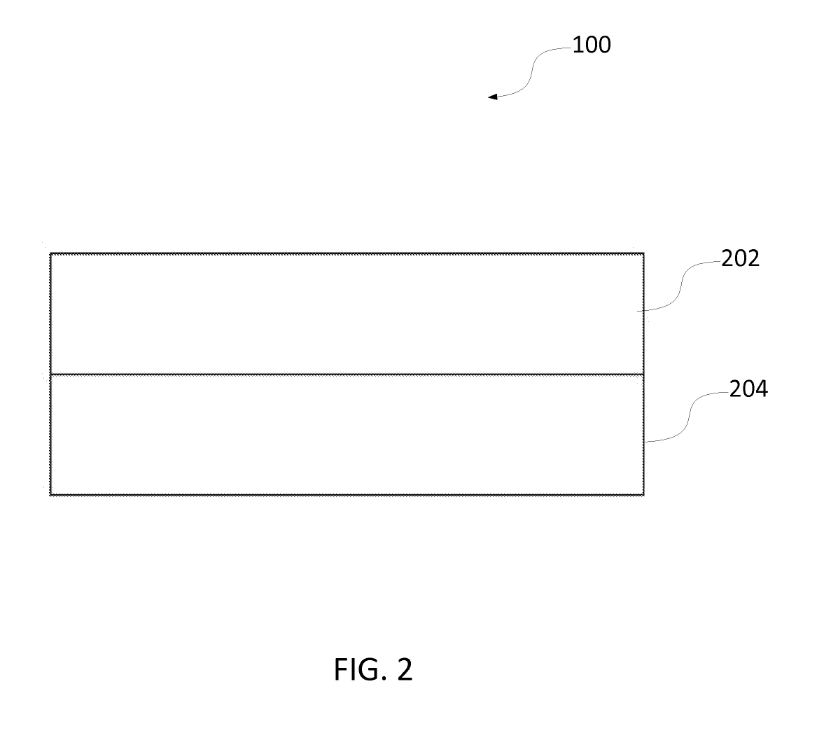

FIG. 2 is a cross-sectional view of two stacked semiconductor dies forming an image sensor of FIG. 1 along the section line Z-Z′. Image sensor 100 includes a sensor die 202 and a circuit die 204. In this view, it can be seen that the circuit die 204 is communicatively coupled to the sensor die 202. For example, the circuit die 204 may underlie the sensor die 202.

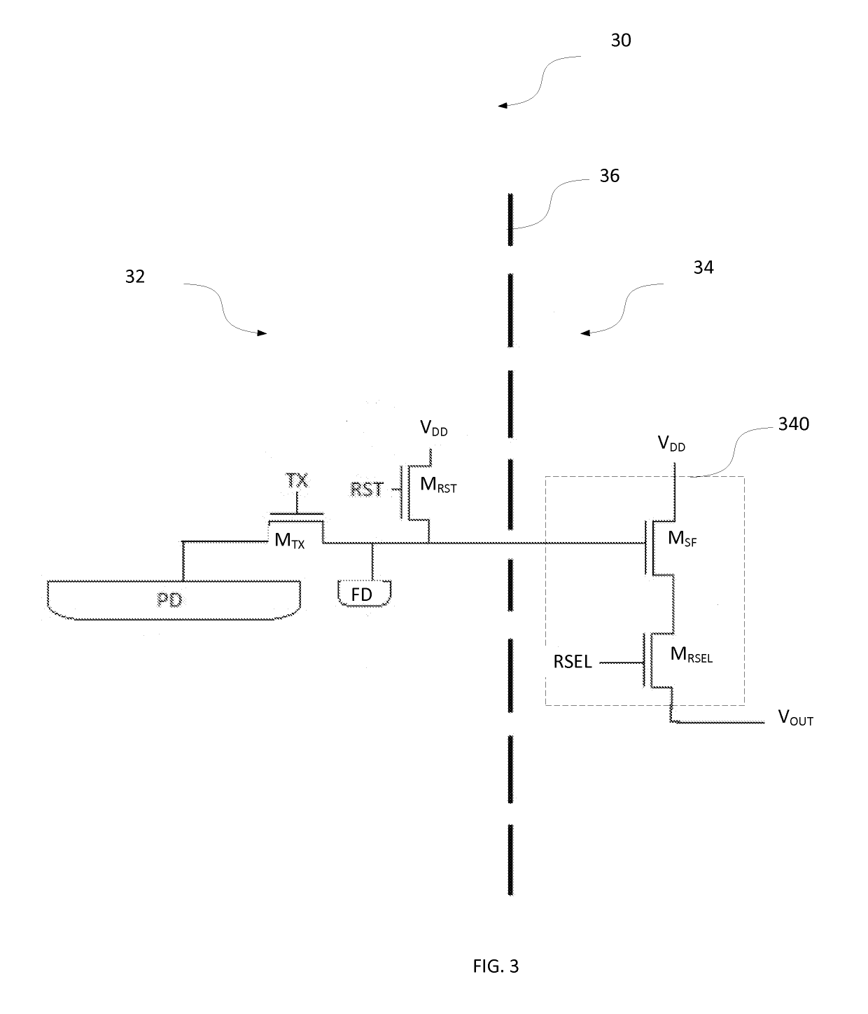

FIG. 3 is a schematic diagram of a stacked image sensor with a floating diffusion region in a sensor die according an embodiment of the invention. An active pixel sensor 30 includes a sensor die 32 and a circuit die 34. The dotted line 36 represents a die border between two dies 32 and 24. Each sensor die 32 comprises a plurality of pixels. Each pixel includes a light sensitive element, a transfer gate M_{TX}, a floating diffusion region FD, a reset gate M_{RST}, and a voltage potential V_{DD}. The reset gate M_{RST} resets the floating diffusion region FD to a fixed voltage. Note that a photodiode PD is shown in FIG. 3 as the light sensitive element, but it can be appreciated that other types of light sensitive elements can be easily substituted for the photodiode, such as a pinned photodiode, photogate, phototransistors, etc. Thus, the term photodiode, as used herein, shall mean any light sensitive element that can convert incident light into an electrical signal. The transfer gate M_{TX} is configured between the photodiode PD and the gate of the source follower M_{SF}. Both the transfer signal bus TX and the reset signal bus RST are located in the sensor die 32.

Each circuit die 34 comprises a plurality of processing and amplification circuits 340 associated with the reset gates M_{RST} of the sensor die 32. The sensor die 32 is interconnected with the circuit die 34 utilizing a plurality of inter-die interconnects (not shown in FIG. 3) each coupled to a source node of a reset gate M_{RST} on the sensor die 32 and a node of a processing and amplification circuit 340 on the circuit die 34.

Alternatively, the processing and amplification circuit 340 comprises a source follower transistor M_{SF} and a row selector transistor M_{RSEL}, wherein a drain of the row selector transistor M_{RSEL} is connected to a source of source follower transistor M_{SF}. A source of the row selector transistor M_{RSEL} is connected to output (V_{OUT}). The source follower transistor M_{SF} amplifies the signal on the floating diffusion region FD when the signal on the floating diffusion region FD is to be read out.

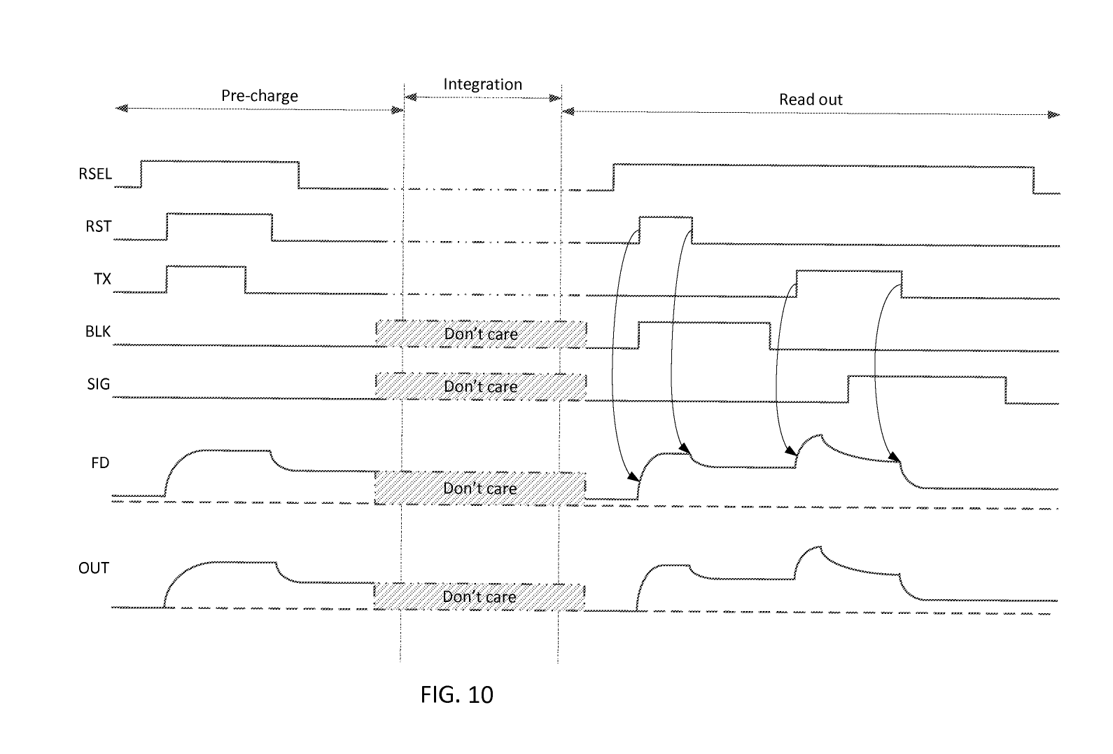

FIG. 10 shows a timing for the operation of the sensor 30. There are three periods in general.

First, in the Pre-charge (or reset) period. The reset gate M_{RST} is on, the transfer gate M_{TX} is on, photodiode PD is reset to full depletion. Then the transfer gate M_{RX} is off followed by the turning off of the reset gate M_{RST}.

Then comes the integration period. Basically the transfer gate M_{TX} is off in the integration period. The reset gate M_{RST} can be on so floating diffusion region FD is connected to VDD so as to reduce overflow. The reset gate M_{RST} can be off too. Basically status of the floating diffusion region FD will not impact the function of pixel.

Then follows the Readout period. The row selector transistor M_{RSEL} is on, which is used to select the line to read out. The row selector transistor M_{RSEL} is turned on briefly to allow the signal output by the source follower transistor M_{SF} to be placed on the readout line V_{OUT}. An image sensor is read out one row at a time. That means that only one row selector transistors M_{RSEL} in the whole image array are “on” at any point in time. All the other rows have their M_{RSEL} transistors turned “off”. However, the row selector transistor M_{RSEL} is optional. When the row selector transistor M_{RSEL} is omitted, the source follower M_{SF} can act as a row select device when the row is not selected. Biasing the floating node to a voltage below source follower threshold voltage, the source follower will be “off”. “VDD” at drain of reset transistor M_{RST} will act as a clock in this case. (VDD is above the source follower threshold when row is selected for reset and readout, and VDD is below the source follower threshold when row is not selected). Then the reset gate M_{RST} is on to reset the floating diffusion region FD. A signal BLK is on to store a black reference signal. The reset gate M_{RST} is off before the signal BLK is off so that the kTC noise generated by the reset gate M_{RST} turning off will be stored. Then the transfer gate M_{TX} is on, which enables transfer charge from the photodiode PD to the floating diffusion region FD. Then the SIG is on to store signal. The transfer gate M_{TX} is off before SIG is off so the charge injection of the transfer gate M_{TX} will not be stored.

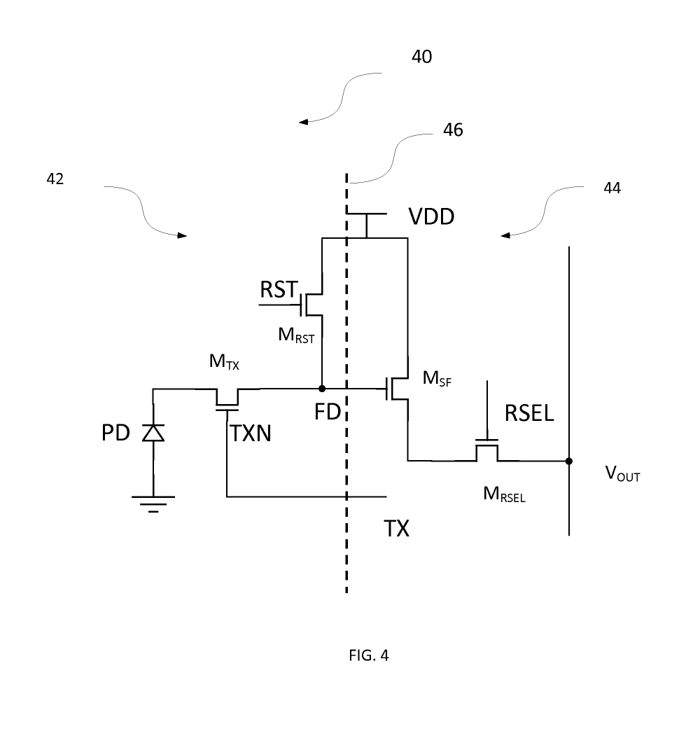

FIG. 4 is a schematic of a stacked image sensor in accordance with another embodiment of the invention. In FIG. 4, an active pixel sensor 40 includes a sensor die 42 and a circuit die 44, wherein same reference signs represent same elements in the active pixel sensor 30 shown in FIG. 3, the detail descriptions of which are omitted. The dotted line 46 represents a die border between two dies 32 and 24. As shown in FIG. 4, the transfer signal bus TX is located in the circuit die 44, so as to save space on the sensor die 42 for accommodating a larger photo detector on the sensor die 42. In other words, the transfer node TXN on the sensor die 42 is interconnected to the transfer signal bus TX in the circuit die 44.

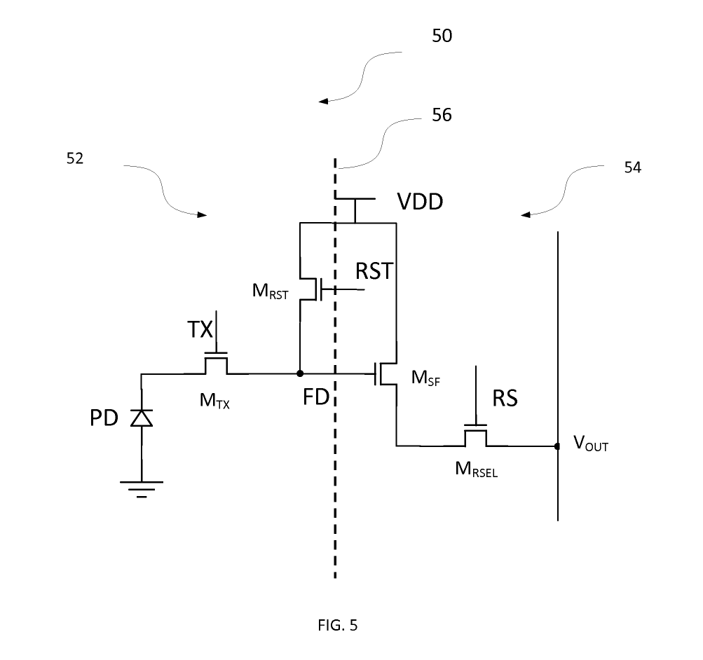

FIG. 5 is a schematic of a stacked image sensor in accordance with another embodiment of the invention. In FIG. 5, an active pixel sensor 50 includes a sensor die 52 and a circuit die 54, wherein same reference signs represent same elements in the active pixel sensor 30 shown in FIG. 3, the detail descriptions of which are omitted. The dotted line 56 represents a die border between two dies 52 and 54. As shown in FIG. 5, the reset bus RST is located in the circuit die 54, so as to save space on the sensor die 52 for accommodating a larger photo detector on the sensor die 52. In other words, the reset node RSTN on the sensor die 52 is interconnected to the reset signal bus RST in the circuit die 54.

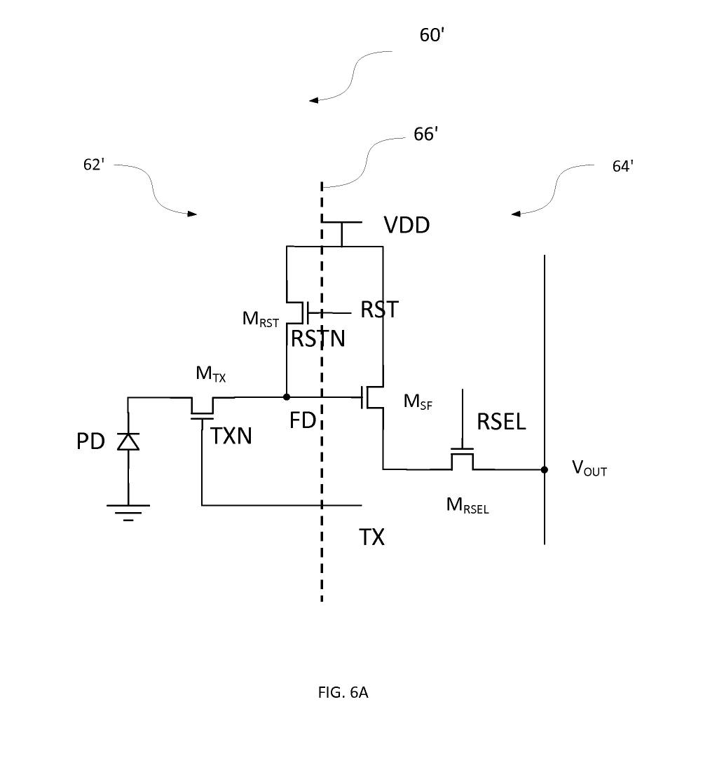

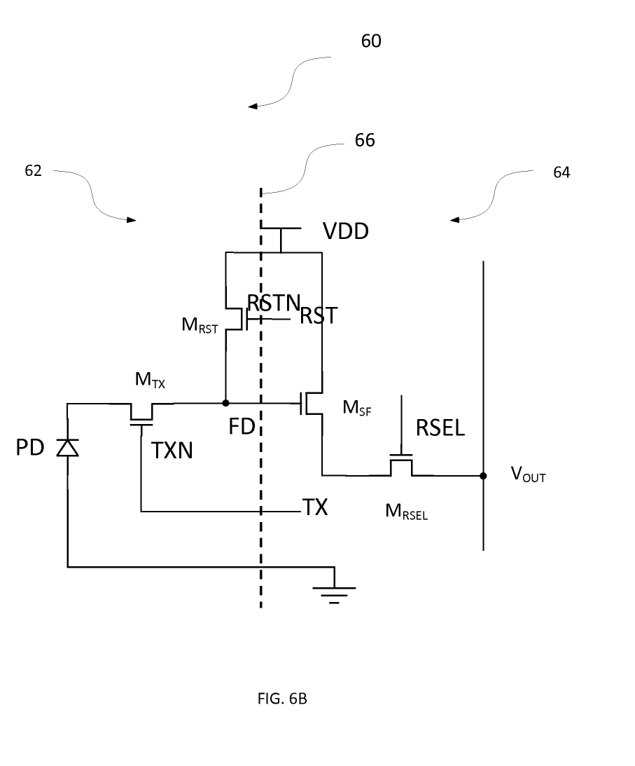

FIG. 6A is a schematic of a stacked image sensor in accordance with another embodiment of the invention. In FIG. 6A, an active pixel sensor 60 includes a sensor die 62 and a circuit die 64, wherein same reference signs represent same elements in the active pixel sensor 30 shown in FIG. 3, the detail descriptions of which are omitted. The dotted line 66 represents a die border between two dies 62 and 64. As shown in FIG. 6A, both the reset signal bus RST and the transfer signal bus TX are located in the circuit die 64, so as to save space on the sensor die 62 for accommodating a larger photo detector on the sensor die 62. In other words, the reset node RSTN on the sensor die 62 is interconnected to the reset signal bus RST in the circuit die 64, and the transfer node TXN on the sensor die 62 is interconnected to the transfer signal bus TX in the circuit die 44.

FIG. 6B is a schematic of a stacked image sensor 60′ in accordance with another embodiment of the invention. The transfer gate M_{TX} is in the same die as the photodiode PD so to avoid contact requirements. The photodiode PD is surrounded with pure silicon crystal so to avoid defect which may lead to dark current, or defect pixel, etc. Although not shown in FIG. 6B, there is no metal layer in the sensor die 62′, so as to reduce cost. Therefore, the transfer bus TX is located in the circuit die 64′, and the ground bus is located in circuit die 64′.

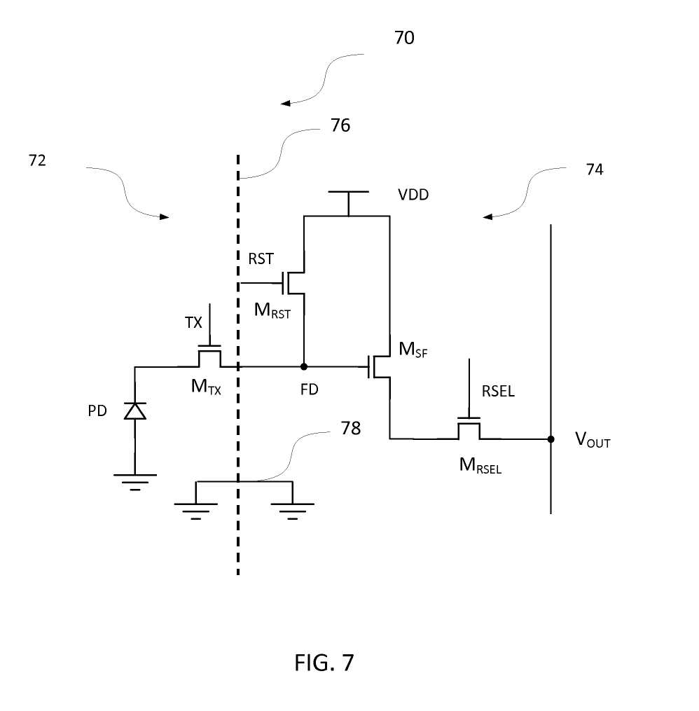

FIG. 7 is a schematic of a stacked image sensor in accordance with another embodiment of the invention. In FIG. 7, an active pixel sensor 70 includes a sensor die 72 and a circuit die 74, wherein same reference signs represent same elements in the active pixel sensor 30 shown in FIG. 3, the detail descriptions of which are omitted. The dotted line 76 represents a die border between two dies 72 and 74. As shown in FIG. 7, the floating diffusion region FD is located in the circuit die 74. The reset signal bus RST is located in the circuit die 74, so as to save space on the sensor die 52 for accommodating a larger photo detector on the sensor die 52. Note that although FIG. 7 shows a ground connector 78, those having ordinary skill in the art should appreciate that the ground connecter 78 can be omitted, and the sensor wafer 72 and the circuit wafer 74 do not need to be connected by the ground connector 78.

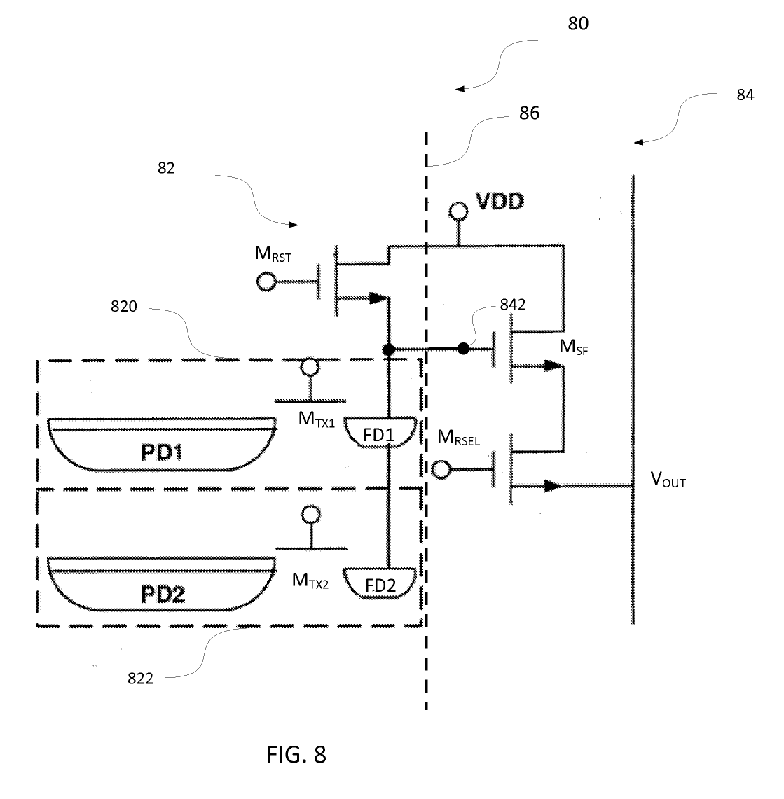

Referring now to FIG. 8, there is shown a schematic diagram of a shared processing and amplification architecture that can be implemented in an image sensor having two semiconductor dies in an embodiment in accordance with the invention.

An image sensor utilizing this architecture includes a sensor die 82 with pixels that include a first photodiode PD1, a first transfer gate M_{Tx1}, a first float diffusion region FD1, a second photodiode PD2, a second transfer gate M_{Tx2}, and a second float diffusion region FD2. The first photodiode PD1, the first transfer gate TG1, and the first float diffusion region FD1 are associated with a first pixel 820 while the second photodiode PD2, the second transfer gate M_{Tx2}, and the second float diffusion region FD2 are associated with a second pixel 822. Although only two pixels 820, 822 are shown in FIG. 8, an image sensor can include additional pixels in an embodiment in accordance with the invention.

Each pixel has its own photodiode, and the two pixels 820, 822 share a reset gate M_{RST}. The two pixels 820, 822 further share a processing and amplification circuit in the circuit die 84. Each of the pixels has its output going to the same shared processing and amplification circuitry in the circuit die 84. Both first and second float diffusion regions FD1 and FD2 on the sensor die 82 are connected electrically to node 842 on the circuit die 84 using inter-die contact in an embodiment in accordance with the invention. Although the first and second float diffusion regions FD1 and FD2 shown in FIG. 8 are separate, those having ordinary skill in the art understand that the first and second float diffusion regions FD1 and FD2 can be an integrated one and shared by the first photodiode PD1 and the second photodiode PD2. As shown in FIG. 8, every two pixels share a same reset gate M_{RST} and a same processing circuitry. As the shared processing circuitry is on another separate circuit die 84, the sensor die 82 needs to convey the signal over to the circuit die 84. The signal is conveyed using a floating node FD (842). It is the back end processing circuitry that is shared by a plurality of pixels on a sensor die.

Although not shown in FIG. 7, the ground signal bus may be located on the circuit die 84, and the substrate contacts of the sensor die 82 are interconnected to the ground signal bus in circuit die 84.

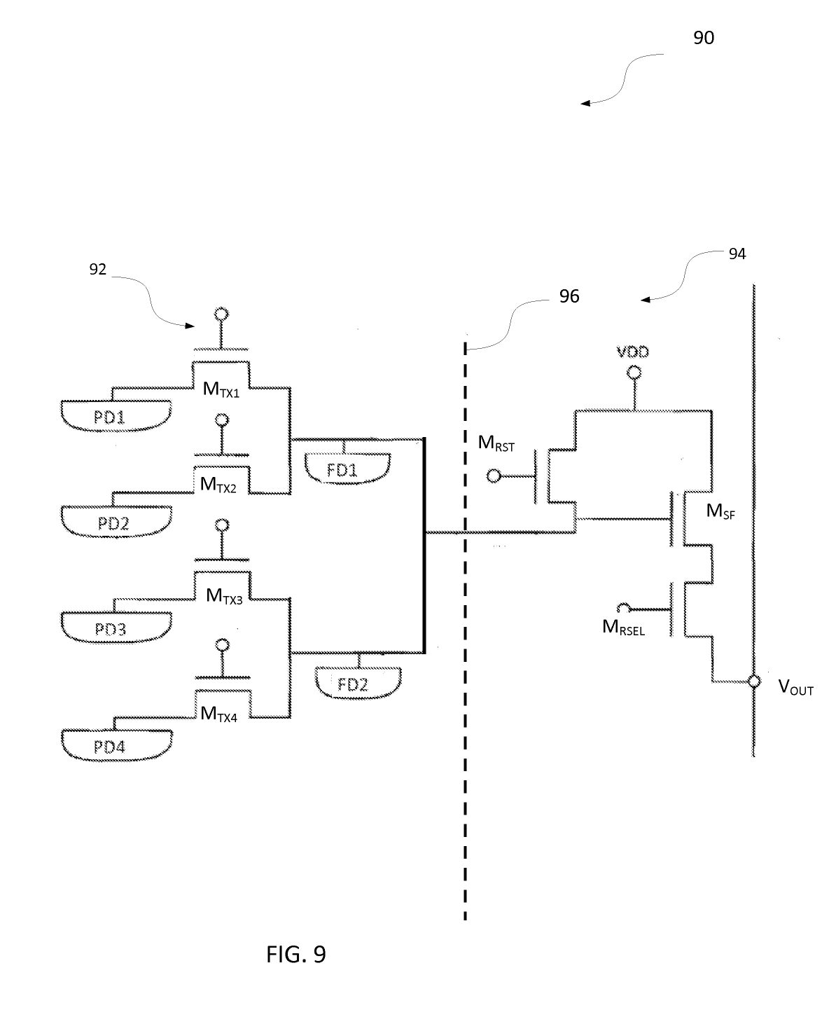

Further, there can be one float diffusion region FD contact between sensor die and circuit die within every two pixels, those having ordinary skill in the art can understand that the FD contact within every 1, 2, 4, or N×M pixels can also be applied to the embodiments of the invention, as will be discussed below with reference to FIG. 9. As every 2 or 4 or 8 pixels might share the readout and amplification transistors, it lowers the amount of transistors needed in circuit die. Further, more pixels share readout can reduce the contact between circuit die and sensor die that will make manufacturing process easier.

Further, node 842 connects to the gate of source follower transistor M_{SF} and the source of reset gate transistor M_{RST}. The drains of M_{RST} and source follower transistor M_{SF} are maintained at voltage potential VDD. The source of source follower transistor M_{SF} is connected to the drain of row selector transistor M_{RSEL}, and the source of M_{RSEL} is connected to output V_{OUT}.

Alternatively or in addition, for example, there are two metal layers (a first metal layer and second metal layer) in a sensor die 82. The floating diffusion region connects to a first metal through contact, and then the floating diffusion region connects to the second metal layer through via. The second metal layer in the sensor die 82 then is interconnected to a top metal in a circuit die 84.

As shown in the schematic diagram of FIG. 9, photodiodes PD1 and PD2 share a common first floating diffusion region FD1, and photodiodes PD3 and PD4 share a common second floating diffusion region FD2. Each of the photodiodes PD1, PD2, PD3 and PD4 has an associated transfer gate M_{TX1}, M_{TX2}, M_{TX3} and M_{TX4} respectively. The four transfer gates M_{TX1}, M_{TX2}, M_{TX3} and M_{TX4} couple the respective photodiodes to the shared floating diffusion region FD1 or FD2.

Both of the floating diffusion regions FD1 and FD2 of the sensor die 92 are coupled to a processing and amplification circuitry for processing signals generated by the photodiodes PD1, PD2, PD3 and PD4. This additional circuitry comprises a reset gate M_{RST}, a source follower transistor M_{SF}, and a row selector transistor M_{RSEL}. This processing and amplification circuitry is coupled between a supply voltage VDD and an output voltage V_{OUT}. It is apparent from FIG. 9 that the set of processing and amplification circuitry is shared by the four photodiodes PD1, PD2, PD3 and PD4 of the sensor die 92.

Alternatively or in addition, several pixels can share substrate interconnection via, so as to reduce total interconnection via number.

The floating diffusion region has high N+ implant dosage and high concentration, which result in increased floating diffusion junction leakage current and defects. With the application of the embodiments of invention, since the floating diffusion region is located in sensor die, the issue of leakage current and defects are alleviated by using special process. As for the circuit die, general process can be used.

Features and aspects of various embodiments may be integrated into other embodiments, and embodiments illustrated in this document may be implemented without all of the features or aspects illustrated or described. One skilled in the art will appreciate that although specific examples and embodiments of the system and methods have been described for purposes of illustration, various modifications can be made without deviating from the spirit and scope of the present invention. For example, embodiments of the present invention may be applied to image sensors having different types of light sensing devices, such as photodiodes, photogates, pinned photodiodes, and equivalents. Moreover, features of one embodiment may be incorporated into other embodiments, even where those features are not described together in a single embodiment within the present document. Accordingly, the invention is described by the appended claims.

I/We claim:

1. An active pixel sensor comprising:
a sensor die comprising
a plurality of pixels, wherein each pixel includes a light sensitive element and a transfer gate, a floating diffusion region, and a reset gate; and
a circuit die comprising a plurality of processing and amplification circuits associated with the reset gates of the sensor die;
wherein the sensor die is interconnected with the circuit die utilizing a plurality of inter-die interconnects each coupled to a source node of the reset gate on the sensor die and a node of a processing and amplification circuit on the circuit die.

2. The active pixel sensor of claim 1, wherein the circuit die does not include a floating diffusion area.

3. The active pixel sensor of claim 1, wherein each inter-die interconnects further couples the floating diffusion region on the sensor die and the node of the processing and amplification circuit on the circuit die.

4. The active pixel sensor of claim 1, wherein the plurality of processing and amplification circuits each comprises a source follower transistor and a row selector transistor, wherein a drain of the row selector transistor is connected to a source of the source follower transistor.

5. The active pixel sensor of claim 1, wherein the transfer gate is controlled by a transfer signal bus on the circuit die.

6. The active pixel sensor of claim 1, wherein the light sensitive element is connected to a ground connector in the circuit die.

7. The active pixel sensor of claim 1, wherein the transfer gate is controlled by a transfer signal bus on the sensor die.

8. The active pixel sensor of claim 1, wherein the reset gate is controlled by a reset signal bus on the sensor die.

9. The active pixel sensor of claim 1, wherein the reset gate is controlled by a reset signal bus on the circuit die.

10. The active pixel sensor of claim 1, wherein the floating diffusion region collects charge from a pixel of the sensor die.

11. The active pixel sensor of claim 1, wherein the floating diffusion region collects charge from a plurality of pixels of the sensor die.

12. The active pixel sensor of claim 1, wherein the reset gate resets the charge collected at a floating diffusion region.

13. The active pixel sensor of claim 1, wherein the reset gate resets the charge collected at a plurality of floating diffusion region of the sensor die.

14. The active pixel sensor of claim 1, wherein the light sensitive element comprises a photodiode.

15. An active pixel sensor comprising:
a sensor die comprising
a plurality of pixels, wherein each pixel includes a light sensitive element and a transfer gate, a plurality of floating diffusion regions associated with the plurality of transfer gate; and
a circuit die comprising
a plurality of reset gates and a plurality of processing and amplification circuits;
wherein the sensor die is interconnected with the circuit die utilizing a plurality of inter-die interconnects each coupled to a drain node of a transfer gate on the sensor die and a node of a floating diffusion region on the circuit die.

16. The active pixel sensor of claim 15, wherein the plurality of processing and amplification circuits each comprises a source follower transistor.

17. The active pixel sensor of claim 15, wherein the floating diffusion region collects charge from a pixel of the sensor die.

18. The active pixel sensor of claim 15, wherein the floating diffusion region collects charge from a plurality of pixels of the sensor die.

19. The active pixel sensor of claim 15, wherein the reset gate resets the charge collected at a floating diffusion region.

20. The active pixel sensor of claim 15, wherein the reset gate resets the charge collected at a plurality of floating diffusion region.

21. The active pixel sensor of claim 15, wherein the light sensitive element comprises a photodiode.

22. The active pixel sensor of claim 15, wherein the transfer gate is controlled by a transfer signal bus on the circuit die.

23. The active pixel sensor of claim 15, wherein the transfer gate is controlled by a transfer signal bus on the sensor die.
